(19) United States
(12) Patent Application Publication
(10) Pub. No.: US 2017/0179391 A1
(43) Pub. Date: Jun. 22, 2017

(54) ORGANIC PHOTOVOLTAIC DEVICES AND METHODS THEREOF

(71) Applicant: University of Massachusetts, Boston, MA (US)

(72) Inventors: Dhandapani Venkataraman, Amherst, MA (US); Monojit Bag, Amherst, MA (US); Timothy S. Gehan, Amherst, MA (US); Christie Laurel Cutting, Enfield, MA (US)

(21) Appl. No.: 15/301,365

(22) PCT Filed: Apr. 24, 2015
(86) PCT No.: PCT/US2015/027436

§ 371 Date: Sep. 30, 2016

Related U.S. Application Data
(60) Provisional application No. 61/983,578, filed on Apr. 24, 2014.

(51) Int. Cl. H01L 51/00

(52) U.S. Cl. CPC H01L 51/0027; H01L 51/0003; H01L 51/4253

(57) ABSTRACT

The invention provides a novel fabrication method to produce solar cells using water-based inks that can be readily used in roll-to-roll processing, ink-jet printing and other large-scale fabrication processes. The invention also provides OPV devices with significantly improved efficiency. The invention offers a number of advantages over existing methods: (1) use of water dispersions instead of environmentally hazardous organic solvents, (2) use of semiconducting nanoparticles that allow control of the domain size and structure, (3) treatment of PEDOT:PSS using UV/Ozone allows film uniformity from aqueoue dispersions, (4) use of heat-IR radiation to make uniform films, (5) use of hole-blocking layer for increased fill factors (squareness of the I-V curve, the ratio between the maximum power obtained and the maximum power obtainable defined by the open circuit voltage and the short circuit current).

### PRIORITY CLAIMS AND RELATED PATENT APPLICATIONS

This application claims the benefit of priority from U.S. Provisional Application Ser. No. 61/983,578, filed on Apr. 24, 2014, the entire content of which is incorporated herein by reference in its entirety.

### PRIORITY CLAIMS AND RELATED APPLICATIONS

This application claims the benefit of U.S. Provisional Application No. 61/983,578, filed Apr. 24, 2014, the entire content of which is incorporated herein by reference in its entirety.

### GOVERNMENT RIGHTS

The United States Government has certain rights to the invention pursuant to Grant No. DE-DC0001087 from Department of Energy to the University of Massachusetts.

### TECHNICAL FIELDS OF THE INVENTION

The invention generally relates to photovoltaic devices and methods. More particularly, the invention relates to novel organic photovoltaic devices and methods for fabricating polymer nanoparticle-based photovoltaic cells.

### BACKGROUND OF THE INVENTION

Organic photovoltaics (OPVs) is a rapidly growing area of research worldwide due to its promise to offer low temperature, inexpensive processing of lightweight and flexible solar cells. OPV cells based on organic polymers are of interest as alternative sources of renewable electrical energy to the typical silicon-based cell. Polymer nanoparticles are widely used in organic electronics, such as sensors, optical imaging and OPVs. (Kietzke, et al. 2004 Macromolecules 37, 4882: Kietzke, et al. 2003 Nat. Mater. 2, 408; Vaughan, et al. 2012 Appl. Phys. Lett. 101; Andersen, et al. 2011 ACS Nano 5, 4188.) Recent development of controlling nanostructure to mesoscale morphology of active layer materials by self-assembly of polymer nanoparticles has shown a great promise for fabricating high efficiency and more reproducible polymer solar cells by roll-to-roll printing. (Labastide, et al. 2011 J. Phys. Chem. Lett. 2, 2089; Labastide, et al. 2011 J. Phys. Chem. Lett. 2, 3085; Krebs, et al. 2009 J. Mater. Chem. 19, 5442.)

Most importantly, processing of solar cells form aqueous based polymer ink is non-toxic compared to current state-of-the-art organic solvent-based OPV technology. Roll-to-roll printing of organic/polymer solar cell requires large amount of toxic halogenated solvent such as chlorobenzene and dichlorobenzene or non-halogenated solvent such as xylene. According to Krebs et. al., approximately 16 million liters of chlorobenzene is necessary to fabricate 1 GWp of polymer solar cell. (Andersen, et al. 2011 ACS Nano 5, 4188.)

Major challenges remain, in particular, with device fabrication from aqueous processing of nanoparticles because of low viscosity and dewetting properties of the polymer ink. Significant difficulties exist with nanoparticle film formation such as surface dewetting leading to surface roughness and lack of control over nanoparticles self-assembly and morphology. Furthermore, the overall power conversion efficiency (PCE) of OPVs fabricated from aqueous dispersions are relatively low.

Thus, there is an urgent un-met need for novel platforms and methodologies for fabricating polymer nanoparticle-based solar cells from aqueous dispersion.

### SUMMARY OF THE INVENTION

The invention provides a novel approach to fabrication of solar cells using water-based inks that can be readily used in roll-to-roll processing, ink-jet printing and other large-scale fabrication processes. The invention offers OPV devices with significantly improved efficiency. OPVs of the invention can have active layers of blend nanoparticles (electron conductor and hole conductors in a single nanoparticle) or separate nanoparticles (electron conductor and hole conductors as two different nanoparticles). Furthermore, the invention allows the incorporation of multiple hole conductors with different absorption characteristics.

The invention addresses key issues of nanoparticle film formation such as surface dewetting leading to surface roughness and lack of control over nanoparticles self-assembly for optimum morphology. Nanoparticle self-assembly in the film is critical to achieve high short circuit current (J_{SC}) and hence high PCE. A thin coating of phenyl-C₆₁-butyric acid methyl ester (PCBM) as electron transporting layer (ETL) reduces the leakage current at the cathode interface and improves the open circuit voltage (V_{OC}) and fill factor (FF) significantly. Additionally, treatment of the substrate surface with UV-O₃ cleaner plays a significant role in improving the wettability and hence reduces the surface roughness of the active layer. Nanoparticle ink formulation is optimized to control the film drying process and nanoparticle self-assembly for better performance of the devices.

In one aspect, the invention generally relates to a photovoltaic device. The device includes: a transparent electrode; an electron-blocking layer; an active layer comprising a plurality of nanoparticles comprising a conjugated polymer; a buffer layer; and a counter electrode. The electron-blocking layer is pre-treated with UV and ozone. The plurality of nanoparticles includes electron conductors and hole conductors.

In another aspect, the invention generally relates to a nanoparticles assembly of photovoltaic devices disclosed herein.

In yet another aspect, the invention generally relates to a method for making a photovoltaic device. The method includes: (1) providing a transparent electrode; (2) forming a dried electron-blocking layer on the transparent electrode; (3) treating the dried electron-blocking layer with UV and ozone; (4) applying under IR radiation, on the treated electron-blocking layer, a layer of an aqueous dispersion of a plurality of nanoparticles comprising a conjugated polymer; (5) drying the layer of aqueous dispersion of a plurality of nanoparticles to form a dried active layer; (6) forming a buffer layer on the dried active layer; and (7) forming a counter electrode on the buffer layer.

In yet another aspect, the invention generally relates to a photovoltaic device produced by the method disclosed herein.

In yet another aspect, the invention generally relates to a method for making a photovoltaic active layer. The method includes: forming an aqueous dispersion of a plurality of nanoparticles of controlled size and morphology under IR radiation, wherein the nanoparticles comprise a conjugated polymer; and drying the layer of aqueous dispersion of a plurality of nanoparticles to obtain a dried photovoltaic active layer.

In yet another aspect, the invention generally relates to a photovoltaic active layer prepared by the method disclosed herein.

### BRIEF DESCRIPTION OF THE DRAWINGS

FIG. 1: Schematic comparing conventional method for preparing organic photovoltaics with the method disclosed herein using nanoparticle based organic photovoltaics.

FIG. 2: (A) Simulated packing of a 1:1 number ratio of two types of particles showing conducting pathways for each set of particles. (B) Simulated packing of a 1:1 number ratio of two types of particles showing conducting pathways for one type of particle (the other being omitted) (C) Top view SEM of a film of P3HT and PCBM separate nanoparticles. Scale bar is 1 μm. (D) Top view SEM of a film of P3HT and PCBM separate nanoparticles after being dipped in dichloromethane for 15 min. Scale bar is 1 μm. (E) A binary scale image of the SEM image in C. (F) A binary scale image of the SEM image in D.

FIG. 3: (A) Conducting AFM image of P3HT and PCBM blend nanoparticles without a PCBM top layer, (B) Conducting AFM image of separate P3HT nanoparticles and PCBM nanoparticles without a PCBM top layer, (C) Conducting AFM image of separate P3HT nanoparticles and PCBM nanoparticles with a PCBM top layer, (D) Histogram depicting normalized pixel count with associated currents measured for two cAFM samples: blend nanoparticles and separate nanoparticles.

FIG. 4: (A) Nanoparticle OPV device performance of P3HT/PCBM blend (1:1 by wt. ratio) NPs and P3HT and PCBM separate (2:1 by no. ratio) NPs. (B) P3HT and PCBM separate (1:1 by no. ratio) NPs size dependent PCE (black squares), and efficiency ratio of separate nanoparticle PCE/blend nanoparticle PCE at varying nanoparticle average diameters (red circles). (C) Nanoparticle OPV device performance metrics when varying the ratio of P3HT NPs to PCBM NPs compared to P3HT/PCBM blend NPs.

FIG. 5 schematically illustrates a prior art process of fabricating OPV and an exemplary embodiment according to the invention.

FIG. 6: (a) Schematic diagram of a polymer nanoparticles based device. (b) Top SEM image of P3HT/PCBM blend (1:1) nanoparticles spin coated on Si substrate. (c) Cross sectional SEM image of P3HT/PCBM blend (1:1) nanoparticles spin coated on Si substrate. A thin layer of PCBM spin coated on top from 15 mg/mL solution in dichloromethane.

FIG. 7: (a) Device parameters variation with the processing condition from P1 to P6. (b) & (c) Typical current-voltage curves for all six types of devices. Filled symbol represents the devices consist of PCBM buffer layer on top.

FIG. 8: Device optimization of P3HT/PCBM blend nanoparticle samples under different heat treatment. All samples were slowly heated from 30 C up to its maximum temperature. Devices were taken of immediately after it reaches the maximum temperature.

FIG. 9: Transmission mode optical microscopic image of P3HT/PCBM blend nanoparticle sample spin coated on (a) as prepared PEDOT:PSS substrate (P1). (b) UV-O₃ treated PEDOT:PSS substrate (P2) (b) as prepared PEDOT:PSS substrate followed by a thin layer of PCBM (P3) (c) UV-O₃ treated PEDOT:PSS substrate followed by a thin layer of PCBM on top from 15 mg/mL concentration in dichloromethane solution (P4).

FIG. 10: (a) AFM image of P3HT/PCBM blend nanoparticles film spin coated on as prepared PEDOT:PSS substrate. Average roughness is −70 nm. (b) Line profile of the AFM image showing large aggregate of sub-micrometer to micrometer range. (c) AFM image of P3HT/PCBM blend nanoparticles film spin coated on UV-O₃ treated PEDOT:PSS coated substrate. Average roughness in ˜10 nm. (c) Line profile of the AFM image showing nanoparticles of the order of 100 nm.

FIG. 11: (a) Intensity dependent I-V curve of a P3HT/PCBM blend nanoparticle device. (b) Device parameters normalized with respect to 100 mW cm⁻² as a function of intensity.

FIG. 12: (a) AFM topographic image of P3HT/PCBM blend nanoparticle device with PCBM buffer layer. (b) C-AFM image of the same area. (c) Line profile of AFM height and current contrast image showing PCBM layer reduces leakage current. (d) AFM height image of the film after washed with DCM. (e) c-AFM image of the same area. (f) Current histogram plot of nanoparticles device with PCBM buffer layer and after DCM washed.

FIG. 13: (a) Current-voltage curve of P3HT/PCBM blend nanoparticle solar cells under AM1.5G (100 mWcm²) illumination of light intensity. 80±20 nm of particle size was used for the devices. Substrates were heated from room temperature (30° C.) to the final temperature at a rate of 5-10° C. min⁻¹ after the cathode electrode was thermally deposited. (b) I-V curve plotted in log scale.

FIG. 14: I-V curve of polymer nanoparticle devices synthesized from different concentration of polymer in chloroform and different amount of surfactant used. The particles sizes vary from 115 nm (60 mg/mL polymer concentration in chloroform added to 1 mM of SDS) to 70 nm (15 mg/mL polymer concentration in chloroform added to 10 mM of SDS). As prepared nanoparticles dispersions are centrifuged different amount of times to optimize ink formulation for spin coating.

FIG. 15: (a) XRD of P3HT/PCBM blend nanoparticles drop casted on glass substrate before the heat treatment and after slowly heated from 30° C. to 150° C. (b) Crystalline size estimated from the width of the XRD peak.

FIG. 16: Comparison of device efficiency under a commercial cool white LED lamp (indoor) and a solar simulator (outdoor) for various devices: a “low end” amorphous silicon commercial device; a “high end” crystalline silicon commercial device; a P3HT and PCBM bulk heterojunction device; a PCE10 PCBM bulk heterojunction device; and an exemplary P3HT PCBM nanoparticle photovoltaic device according to the present invention.

FIG. 17: The emission spectra of the solar simulator lamp used (for outdoor applications) and the LED lamp used (for indoor applications).

### DETAILED DESCRIPTION OF THE INVENTION

The invention provides a novel fabrication methodology for producing solar cells with water-based inks that can be readily used in roll-to-roll processing, ink-jet printing and other large-scale fabrication processes. The invention provides OPVs with significantly improved efficiency. The invention offers a number of advantages over existing methods: (1) use of water dispersions instead of environmentally hazardous organic solvents, (2) use of semiconducting nanoparticles that allow control of the domain size and structure, (3) treatment of PEDOT:PSS using UV/Ozone allows film uniformity from aqueoue dispersions, (4) use of heat-IR radiation to make uniform films, (5) use of hole-blocking layer for increased fill factors (squareness of the I-V curve, the ratio between the maximum power obtained and the maximum power obtainable defined by the open circuit voltage and the short circuit current).

Organic solar cells are semi-transparent, thin, lightweight, and flexible. Simply put, they can be attached into anything, anywhere and in any size. Typical OPV cells contain: a transparent electrode, typically indium tin oxide; an electron-blocking layer (typically PEDOT:PSS); active layer consisting of conjugated polymers and molecules; a hole-blocking layer; and a counter electrode. Conventional fabrication process of OPVs involves the following steps: (1) spin-coating an aqueous solution of poly(3,4-ethylenedioxythiophene) poly(4-styrenesulfonate sodium salt) (PEDOT:PSS) on indium doped tin oxide (ITO) substrate and drying in air, (2) spin-coating of a halogenated arene solution of conjugated molecules or polymers (hole conductors) and conjugated molecules or polymers (electron conductors); the solution may also contain an additive, (3) annealing of the active later at elevated temperatures if needed, (4) coating of the counter electrode. Step 3 is sometimes done after step 4. Typically, a hole-blocking layer is not explicitely added after step 3 as it is believed that during the annealing process, some amount of electron conductor moves to the interface serving as a hole-blocking layer. At large-scale fabrication, instead of spin-coating, roll-to-roll process may be used for fabricating OPVs.

There are two major disadvantages to this conventional fabrication process. One is the use of halogenated arene solvents. Large scale manufacturing of OPVs using such solvents posts significant environmental issues. Second, there is little to no control in terms of morphology obtained in the active layers.

The active layer of OPVs consists of two semiconducting materials: an electron donor (hole-transporting) and an electron acceptor (electron-transporting) that are arranged in a multi-length scale morphology comprised of a mesoscale network of hole-conducting fibrils embedded in a matrix of the electron and hole conductors. There is a strong process dependence of the morphology, influenced by the solvents and additives, their vapor pressures, the ordering and aggregation kinetics of the polymers, de-mixing, and post-processing conditions. Consistently achieving such complex kinetically-trapped morphologies has been challenging as it depends on the interplay of multiple kinetic processes.

Disclosed herein is the novel approach of sphere packing designed to reliably fabricate multi-scale hierarchical active layer structures through self-assembly when active layer materials are fabricated as nanospheres. To help control the morphology of the active layer, polymer nanoparticles have been used as active layers. Geometric packing is emerging as a powerful tool to realize nanoscale and mesoscale structures or morphologies. A sphere is a common geometry in nanoscale structures and two types of spheres can be co-assembled into various geometries based on their radius ratio. The efficacy of this approach is demonstrated by fabricating OPVs in ambient atmosphere using poly(3-hexylthiophene) (P3HT) and [6,6]-phenyl-C₆₁-butyric acid methyl ester (PCBM) as active layer materials.

This unique approach affords several significant advantages over the conventional methodology, including the ability to (a) tailor the semiconductor domains with the required internal packing and size; (b) obtain stable co-continuous structures that are controlled from nano- to mesoscale through a single step self-assembly into equilibrium or kinetically-trapped morphologies; (c) systematically alter the packing of the semiconductor through changes in the sizes and shapes of the nanoparticles; (d) use multiple hole conductors to broaden the absorption spectrum; (e) systematically elucidate the optimal structure for an efficient OPV device and (0 use environmentally benign water-based solvents for device fabrication.

Spheres can assemble into ordered superlattices or randomly packed jammed assemblies depending on sphere-sphere interactions, size dispersity, and size ratios. If sphere-to-sphere contacts are allowed, both assemblies can provide morphologies with interfaces for charge transfer and continuous pathways for charge transport, which are two key requirements for OPV devices. In inorganic nanoparticle assemblies, particle-particle contacts are prevented by the ligands strongly bound to the surface of the nanoparticles leading to poor charge transport. In organic nanoparticle assemblies, the particle-particle contacts are easily established because the weakly bound surfactants can be dislodged by strong van der Waals interactions between the nanoparticles leading to efficient charge transport. However, these strong particle-particle interactions often lead to jammed instead of ordered assemblies. Computations indicate that jammed co-assemblies, much like in ordered binary superlattices, can also provide co-continuous structures and the morphology is dictated by the radius ratio of the spheres. Thus, jammed assemblies of single and binary conjugated polymer nanospheres provide a new approach to achieve and fine tune the morphology required for active layers in organic photovoltaic devices.

The capability to utilize sphere packing to realize active layer structures in blended nanoparticles and in separate nanoparticles is demonstrated using P3HT and PCBM, the archetypical active layer materials in OPVs. Blended nanoparticles have electron and hole transporters in the same nanoparticle, which offers a unique pathway to create bulk heterojunction (BHJ)-type structures at the nanoscale, i.e., in a single nanoparticle, and propagate this structure to the mesoscale through self-assembly. Furthermore, isolating active layer materials as separate nanoparticles prior to their co-assembly allows the control of the size, tailoring the structure and ordering within, and controlling the surface characteristics of the nanoparticles. These unique attributes enable the formation of domains having pre-defined sizes, independently tailored ordering, and well-defined contacts (interfaces) between the electron and hole conducting domains.

The blend nanoparticles and separate nanoparticles were fabricated using a modified mini-emulsion technique. The mode diameter of the nanoparticles was calculated to be 80 nm±8 nm and 74 nm±11 nm (P3HT and PCBM), respectively, using nanoparticle-tracking analysis. The P3HT packing within the nanoparticle was probed using electronic spectroscopy. The UV-Vis spectrum of P3HT can be deconvoluted into absorption arising from aggregate P3HT and from amorphous P3HT peak. From the deconvoluted UV-vis absorption data, it was estimated that the ratio of aggregate to amorphous P3HT was 70:30 in blend and in separate P3HT nanoparticles. The amorphous component was attributed to P3HT within the nanoparticle and not to free P3HT as P3HT is insoluble in water. Since both blend and separate nanoparticles show a similar ratio of amorphous P3HT to aggregate P3HT, it was concluded that PCBM does not significantly affect P3HT aggregate formation in the blend nanoparticles. Much like in BHJ, the PCBM is expected to concentrate in amorphous or non-aggregated domains of P3HT. The UV-vis spectrum of both the blend nanoparticle and separate nanoparticle dispersions of similar size and concentration shows spectral features similar to that of annealed thin films of P3HT and PCBM from chlorobenzene indicating that the features desired in thin films can be captured in the nanoparticles.

Scanning electron microscopy (SEM) images of the spin-coated assemblies of blend nanoparticles and co-assembly of P3HT and PCBM nanoparticles (1:1) show that the nanoparticle form jammed assemblies with particle-particle contacts.

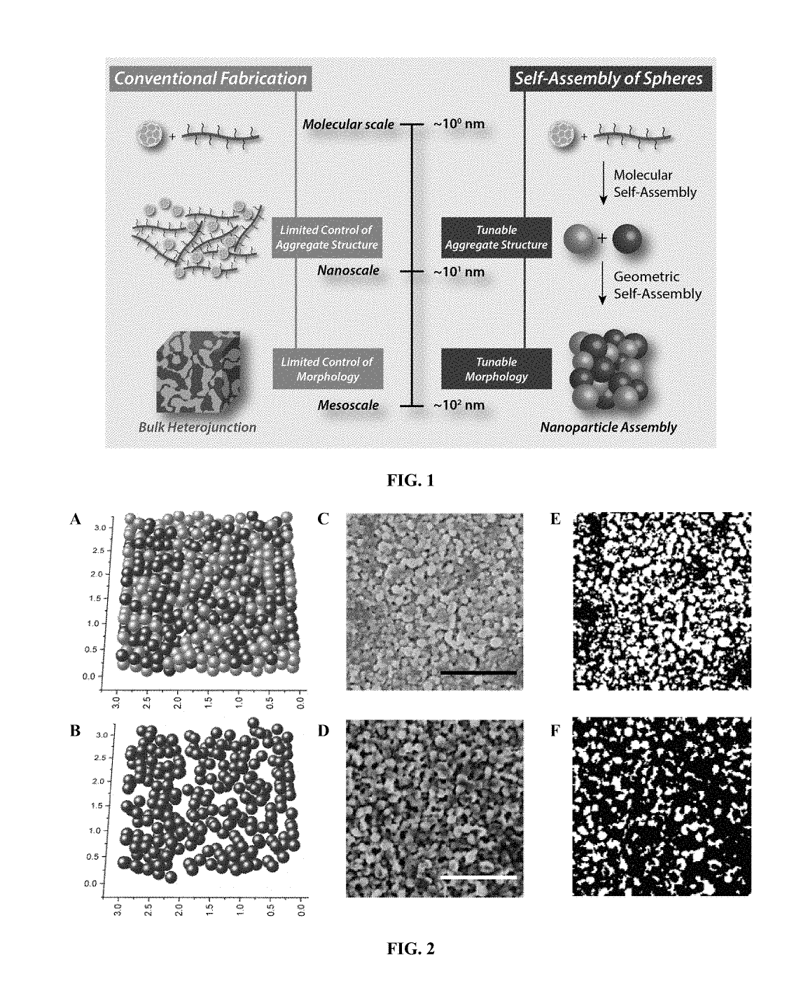

FIG. 1 shows a schematic that compares conventional method for preparing organic photovoltaics with the method disclosed herein using nanoparticle based organic photovoltaics. FIG. 2A depicts simulated packings of two types of particles showing conducting pathways for each set of particles.

After the removal of PCBM, the void spaces in the film are visible indicating that the films are jammed co-assembly of P3HT and PCBM nanoparticles. Cross sectional SEM of a thin film of blend nanoparticles of P3HT and PCBM with a PCBM buffer layer spin coated on top confirms that the nanoparticles are closely packed throughout the film. The SEM also shows that the PCBM top layer remains between the nanoparticle active layer and the electrode and thus acts as a buffer layer. Similar results were also observed for separate nanoparticle active layers.

Conducting atomic force microscopy (c-AFM) was used to probe the conducting pathways in the active layer. c-AFM images of assemblies of blend nanoparticle and co-assemblies of separate nanoparticles (˜240 nm thick films) on ITO/PEDOT:PSS are shown in FIG. 3. The images were recorded under reverse-bias conditions using a platinum tip. Therefore, the recorded current is a result of the movement of holes to the platinum tip. The dark red regions in the images are areas of high hole conductivity and the blue regions are areas of low conductivity.

Results show that there are continuous pathways for holes in the jammed assemblies and co-assemblies of nanoparticles. Both FIG. 3a (blended nanoparticles) and FIG. 3b (separate nanoparticles) indicate that there are conductive pathways for holes to be transported through the nanoparticle film to the platinum tip electrode. c-AFM of a film of only P3HT nanoparticles shows uniform high conductivity throughout the film indicating uniform hole transport. Whereas c-AFM of a film of only PCBM nanoparticles shows low conductivity uniformly throughout the film and thus indicating minimal hole transport. The areas of low current in FIG. 3a and FIG. 3b are regions with either a high concentration of PCBM or regions surrounded by PCBM. c-AFM image of a thin film of blend P3HT and PCBM nanoparticles with a thin coating of PCBM on top is shown in FIG. 3c. The corresponding height image indicates that the PCBM top layer reduces surface roughness of the nanoparticle film and FIG. 3c indicates the PCBM top layer blocks many pathways for holes to reach the top electrode thus reducing the leakage current. Similar results were found for a thin film of co-assembly of separate nanoparticles with a PCBM top layer.

Histograms of the current mapping provide evidences to the underlying device morphology. The number of counts is related to the number of available paths for hole conduction, and the current value is related to path length and resistance. FIG. 3d is a histogram of pixel count vs thickness normalized current for the c-AFM samples in FIG. 3a (blend nanoparticles) and FIG. 3b (separate nanoparticles). The histograms for the two samples are different indicating that there is a morphological difference between the blended and separate nanoparticle films. This histogram also shows the separate nanoparticle film has a slightly larger average normalized current than the blend nanoparticle film. The peak width is larger for separate nanoparticles than it is for blend nanoparticles, indicating there is a wider distribution of pathways with separate nanoparticles and thus there are more pathways that are shorter (or low resistance) compared to blend nanoparticle assemblies.

Thus, the c-AFM results demonstrates that (a) there are conductive pathways for holes through the bulk of both blend and separate nanoparticle films and (b) there is a morphological difference how the active layer materials pack in blend and separate nanoparticles, affecting how the charges transport through the bulk of the film.

Times of Flight (TOF) mobility measurement of P3HT, P3HT/PCBM blend and P3HT and PCBM separate nanoparticle films were carried out to determine how effective the charge conduction pathways are through the nanoparticle films. The P3HT nanoparticle film has a hole mobility ˜2×10⁻⁴ 4 cm²V⁻s⁻¹, which is on the same order of magnitude of the pristine P3HT polymer films. A 1:1 mixture of separate P3HT nanoparticles and PCBM nanoparticles shows a hole mobility of ˜8×10⁻⁵ cm²V⁻¹s⁻¹. In both cases a weak field dependence is observed. When the particles were synthesized from 1:1 blended P3HT and PCBM solution, the hole mobility is same as to that of P3HT nanoparticle film at low-field regime, but strong negative field dependence is observed.

Both c-AFM and TOF data indicate there is a difference in the conduction pathways between the blended and separate nanoparticle films.

For fabricating OPV devices, the aqueous dispersion of blend nanoparticles or separate nanoparticles were spin coated on to ITO substrates coated with PEDOT:PSS, which acts as a hole transporting layer. The PEDOT:PSS layer was treated with UV-O₃ for 3 min to increase the surface hydrophilicity and this step was key to achieving uniform films of nanoparticle assemblies. Optical microscopy of nanoparticle films indicates that the average roughness as well as non-uniformity decreases upon UV-O₃ treatment compared to non-treated PEDOT:PSS substrate.

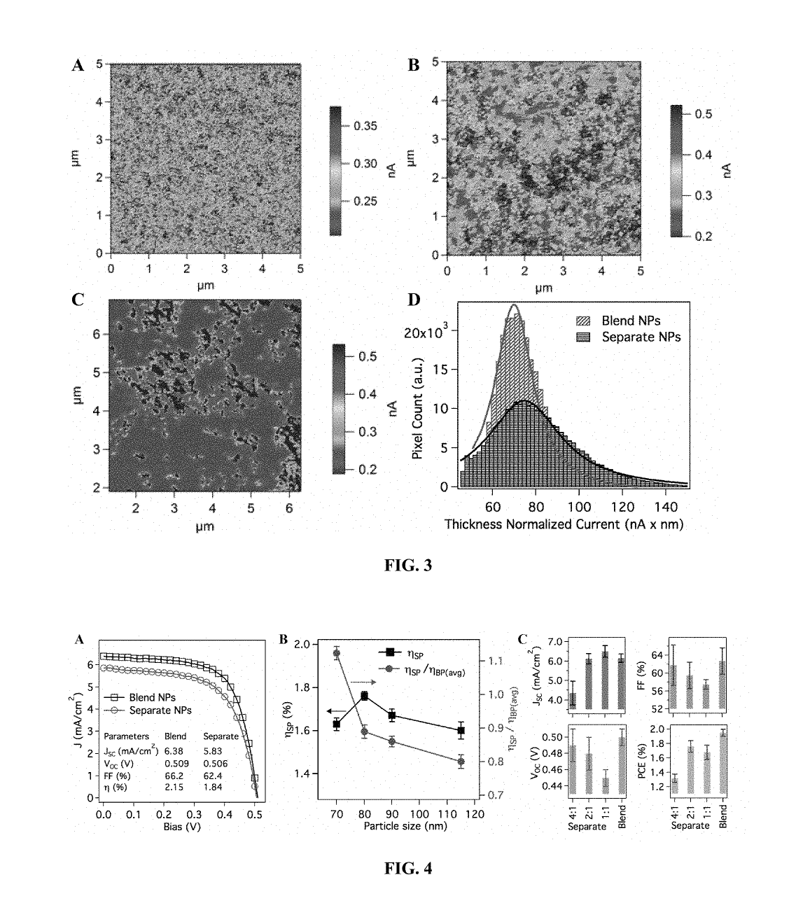

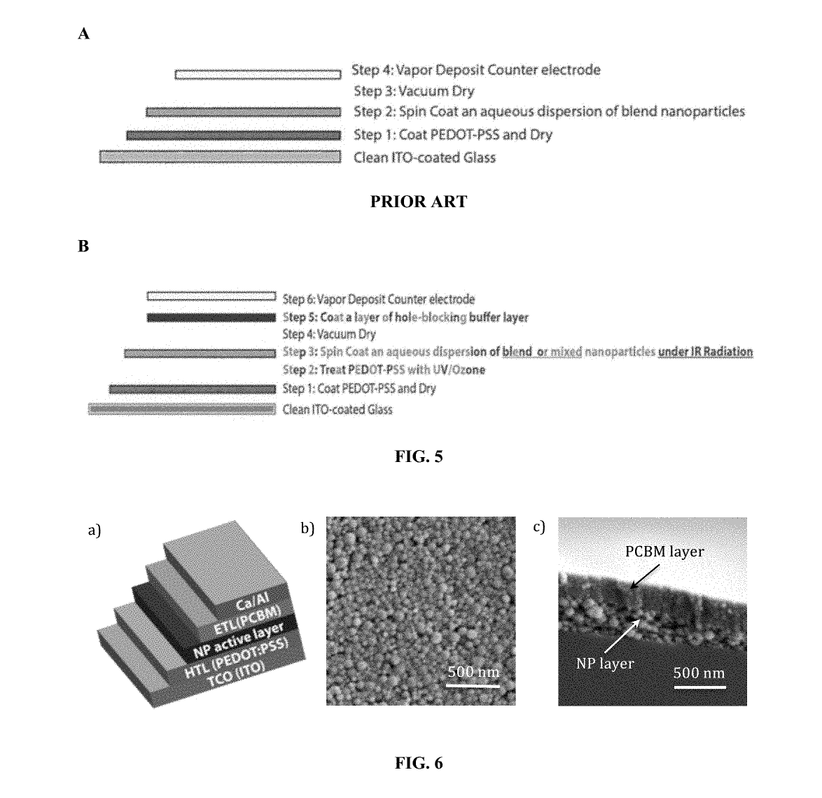

Immediately after treatment, the aqueous dispersion of blend nanoparticles or separate nanoparticles were spin coated on top in the presence of a commercial IR lamp. After drying at room temperature in a vacuum chamber for 12 hours, a thin layer of PCBM as an electron transporting layer (ETL) was spin coated on top of the nanoparticle film and followed by the deposition of the electrode (Ca/Al). This step was key to achieving high fill factor. Except for electrode deposition, all the fabrication steps were done in ambient atmosphere. The highest efficiency was achieved when the dispersion solution is changed to 20% ethanol by volume in water. These dispersions led to the highest device performance for both blend (2.15%) and separate (1.84%) nanoparticles, the current-voltage device performance is shown in FIG. 4a.

To probe the effect of particle size on the OPV device performances, devices from separate and blend nanoparticles were prepared with average diameters ranging from 70 nm to 115 nm. The concentration of P3HT to PCBM was held constant (1:1 weight ratio) for the devices prepared with both blend and separate nanoparticles. Four sets of devices were prepared at four different sizes, keeping the size of the P3HT and PCBM separate nanoparticles the same for each set. The PCE increases from 1.64% to 1.78% in assemblies of separate P3HT and PCBM nanoparticles when the diameter decreases from 115 nm to 80 nm, as seen in FIG. 4b. However, the PCE decreases to 1.66% when 70 nm particles are used the PCE decreases. The red line in FIG. 4b is the ratio in efficiency of separate to blend nanoparticles as the nanoparticle's size changes. This indicates that as the nanoparticle size decreases, the separate nanoparticle devices show better performance than the blend nanoparticle devices. The separate nanoparticles have direct control of the domain size of each component, whereas with blend nanoparticles the domains of the two active layer components will be smaller (smaller than the particle's size) but less controlled than the separate nanoparticles. Since there is direct control over domain size with separate nanoparticles, as the domains get smaller the devices become more efficient than the blend nanoparticles.

Another way to control the morphology is to directly control the ratio of the number of p-type (P3HT) domains to the number of n-type (PCBM) domains. Upon increasing the ratio of P3HT to PCBM nanoparticles from 1:1 to 4:1 the PCE drops from 1.78% to 1.38%. The most efficient ratio of P3HT to PCBM nanoparticles was 2:1 with a maximum efficiency of 1.84%. By controlling the ratio of each nanoparticle, one can directly control the number of domains of each particle within the active layer assuming a random distribution of particles. The drop in efficiency is mainly attributed to a drop in the Jsc. This can be extended with a second donor and/or acceptor to prepare multi component active layers with ease.

The disclosure thus establishes that sphere packing can be utilized to control the hierarchical active layer morphology of organic photovoltaic cells by preforming each active layer component as nanospheres and forming uniform nanosphere assemblies. Controlling the internal morphology within the nanoparticles allows fine-tuning the packing of the active layer materials on the molecular scale. The assembly of the nanoparticle active layer offers significant control over the nanoscale morphology of the active layer, a significant advancement over the conventional methods for fabricating OPVs. Jammed assemblies of nanoparticles have conducting pathways for charges to reach their respective electrodes and can be used for the preparation of efficient OPVs.

FIG. 5B depicts an exemplary embodiment of the fabrication process according to the invention. In (1), the electrodes were coated with as prepared PEDOT:PSS layer. In (2), on the PEDOT:PSS layer was treated with UV-O₃. In (3), active layer was spin coated on as prepared PEDOT:PSS layer under IR lamp radiation. In (4), the active layer was dried under vacuum. In (5), a thin PCBM buffer layer was spin coated on top from 15 mg/mL in dichloromethane solution at 1000 rpm speed for 40 second. In (6), the counter electrodes are deposited on the top.

Furthermore, fabrication of nanoparticles can employ specific reaction vessels with low dead volume under ultrasonication conditions produces a smaller sizes of nanoparticles and narrower size dispersity.

The invention demonstrates the importance of processing methodologies for aqueous-based polymer nanoparticle devices. Polymer solar cells were fabricated from P3HT and PCBM blend and separate nanoparticles of 80±20 nm diameter dispersed in water. Upon spin coating of these nanoparticles active layer on PEDOT:PSS coated ITO substrate from aqueous dispersion shows efficiency up to 2.15% with FF over 66%, highest among all aqueous processing of polymer nanoparticle solar cells. The importance of PEDOT:PSS substrate treatment under UV-O₃ cleaner and the use of PCBM top buffer layer have been highlighted. Relative humidity and substrate temperature during spin coating process also play a significant role on determining the surface roughness and hence the film quality. Morphology of these nanoparticle-based solar cells has been investigated using conducting AFM imaging.

Solar cells with efficiency up to 2.15% have been fabricated from polymer nanoparticles by aqueous processing. Two major challenges, dewetting properties of polymer nanoparticle ink and the assembly of nanoparticles, are addressed by new methodologies such as PEDOT:PSS surface treatment with UV-O₃ and the polymer ink optimization with 20% ethanol addition. The composition of polymer ink plays a significant role to maximize the nanoparticles close packing driven by two nanoscale forces: attractive hydrophobic force and repulsive electrostatic force. The IR lamp and relative humidity control was necessary to derive more random close packed structure from thermodynamically and kinetically trapped assembly of nanoparticles.

Additionally, a PCBM buffer layer was introduced as ETL, which not only reduces the surface roughness but improves the charge extraction at the cathode interface also. FF over 66% has been achieved which is so far highest reported for organic nanoparticle based OPV devices processed from aqueous dispersion. The morphology of the active layer, which is controlled by the hierarchical assembly of nano to mesoscale structure within and of the nanoparticles, results in high FF in these devices. The charge transport properties in the blend nanoparticle film are investigated using conducting probe AFM imaging technique. A uniform distribution of conduction pathways upon removing the buffer layer is consistent with high current density observed in these devices. The methodology developed in this work can be adapted to roll-to-roll printing process, which would make it more attractive to the OPV community.

Thus, in one aspect, the invention generally relates to a photovoltaic device. The device includes: a transparent electrode; an electron-blocking layer; an active layer comprising a plurality of nanoparticles comprising a conjugated polymer; a buffer layer; and a counter electrode. The electron-blocking layer is pre-treated with UV and ozone. The plurality of nanoparticles includes electron conductors and hole conductors.

In certain embodiments, the active layer is formed under IR radiation from an aqueous dispersion of a plurality of nanoparticles comprising a conjugated polymer.

In certain embodiments, the plurality of nanoparticles has a size range from 30 nm to 150 nm (e.g., from 30 nm to 120 nm, from 30 nm to 100 nm, from 30 nm to 80 nm, from 30 nm to 60 nm, from 50 nm to 150 nm, from 70 nm to 150 nm, from 90 nm to 120 nm, from 50 nm to 120 nm, from 70 nm to 120 nm).

In certain embodiments, the plurality of nanoparticles includes nanoparticles each of which comprises both electron conductors and hole conductors. In certain embodiments, each of the plurality of nanoparticles comprises both P3HT and PCBM or its C₇₀ analog. It is noted that in each embodiment of the invention disclosed herein referring to PCBM, there is an embodiment that employs a C₇₀ analog of PCBM.

In certain embodiments, each of the plurality of nanoparticles comprises copolymers derived from diketopyrrolopyrrole and thiophene. In certain embodiments, each of the plurality of nanoparticles comprises copolymers derived from DPP-BT, poly((2-ethylhexyl)oxy benzodithiophene-alt-3-fluoro-2-[(2-ethylhexyl)carbonyl] thieno[3,4-b]thiophene) (PTB7), Poly[2,6-(4,4-bis-(2-ethylhexyl)-4H-cyclopenta [2,1-b; 3,4-b′]dithiophene)-alt-4,7(2,1,3-benzothiadiazole)] (PCPDTBT), 1′,1″,4′,4″-tetrahydro-di[1,4]methano-naphthaleno[5,6]fullerene-C₆₀.

In certain embodiments, the plurality of nanoparticles includes nanoparticles each of which comprises electron conductors and not hole conductors; and nanoparticles each of which comprises hole conductors and not electron conductors.

In certain embodiments, the plurality of nanoparticles includes nanoparticles each of which comprises P3HT and not PCBM; and nanoparticles each of which comprises PCBM and not P3HT.

In certain embodiments, the transparent electrode is made from a material selected from transparent conducting oxides (TCO). In certain embodiments, the transparent electrode is made from indium doped tin oxide (ITO).

In certain embodiments, the counter electrode is made from a material selected from low work-function materials. In certain embodiments, the counter electrode is made from one or both of Ca and Al.

In certain embodiments, the electron-blocking layer comprises UV and ozone-treated PEDOT:PSS. In certain embodiments, the electron-blocking layer comprises UV and ozone-treated MoO₃ or ZnO.

In certain embodiments, the photovoltaic device has a PCE from about 1.5% to about 2.5% (e.g., from about 1.56% to about 2.15%, from about 1.6% to about 2.1%, from about 1.7% to about 2.15%, from about 1.8% to about 2.15%, from about 1.9% to about 2.15%, from about 2.0% to about 2.15%).

In another aspect, the invention generally relates to a nanoparticles assembly of photovoltaic devices disclosed herein.

In yet another aspect, the invention generally relates to a method for making a photovoltaic device. The method includes: (1) providing a transparent electrode; (2) forming a dried electron-blocking layer on the transparent electrode; (3) treating the dried electron-blocking layer with UV and ozone; (4) applying under IR radiation, on the treated electron-blocking layer, a layer of an aqueous dispersion of a plurality of nanoparticles comprising a conjugated polymer; (5) drying the layer of aqueous dispersion of a plurality of nanoparticles to form a dried active layer; (6) forming a buffer layer on the dried active layer; and (7) forming a counter electrode on the buffer layer.

In certain embodiments of the method, the plurality of nanoparticles has a size distribution up to 30% (e.g., 10%, 15%, 20%, 25%, 30%).

In certain embodiments the method, the plurality of nanoparticles includes nanoparticles each of which comprises both electron conductors and hole conductors.

In certain embodiments the method, the plurality of nanoparticles includes nanoparticles that comprise both P3HT and PCBM.

In certain embodiments the method, the plurality of nanoparticles includes nanoparticles each of which comprises electron conductors and not hole conductors; and nanoparticles each of which comprises hole conductors and not electron conductors.

In certain embodiments the method, the plurality of nanoparticles includes nanoparticles each of which comprises P3HT and not PCBM; and nanoparticles each of which comprises PCBM and not P3HT.

In certain embodiments the method, the transparent electrode is made from a material selected from TCOs. In certain embodiments, the transparent electrode is made from ITO.

In certain embodiments the method, the counter electrode is made from a material selected from low work-function materials. In certain embodiments, the counter electrode is made from one or both of Ca and Al.

In certain embodiments the method, the electron-blocking layer comprises UV and ozone-treated PEDOT:PSS.

In yet another aspect, the invention generally relates to a photovoltaic device produced by the method disclosed herein. In certain embodiments the method, the photovoltaic device so produced a PCE of about 1.5% to about 2.5% (e.g., from about 1.56% to about 2.15%, from about 1.6% to about 2.1%, from about 1.7% to about 2.15%, from about 1.8% to about 2.15%, from about 1.9% to about 2.15%, from about 2.0% to about 2.15%).

Nanoparticle assembly is shown to be well suited for all polymer solar cells where macro phase separation due to de-mixing of two polymer components is a major concern. This method provides an alternative technique for multiscale assemblies of nanomaterials for other organic electronics as well. The design methodology disclosed herein open up opportunities for the development of nanoparticle devices with multiple hole transporters with appropriate choice and ratio of acceptor materials.

In yet another aspect, the invention generally relates to a method for making a photovoltaic active layer. The method includes: forming an aqueous dispersion of a plurality of nanoparticles of controlled size and morphology under IR radiation, wherein the nanoparticles comprise a conjugated polymer; and drying the layer of aqueous dispersion of a plurality of nanoparticles to obtain a dried photovoltaic active layer.

In certain embodiments the method, the plurality of nanoparticles have a size distribution up to 30% (e.g., 10%, 15%, 20%, 25%, 30%).

In certain embodiments the method, wherein each of nanoparticles includes both electron conductors and hole conductors.

In certain embodiments, the plurality of nanoparticles includes nanoparticles that comprise both P3HT and PCBM.

In certain embodiments, the plurality of nanoparticles includes nanoparticles each of which comprises electron conductors and not hole conductors; and nanoparticles each of which comprises hole conductors and not electron conductors.

In certain embodiments, the plurality of nanoparticles includes nanoparticles each of which comprises P3HT and not PCBM; and nanoparticles each of which comprises PCBM and not P3HT.

In yet another aspect, the invention generally relates to a photovoltaic active later prepared by the method disclosed herein.

This present invention opens new application and product avenues that are not possible with conventional silicon solar cells. The OPV cells and associated products may be employed for (1) outdoor use where they absorb sunlight and (2) indoor use where they absorb the light emitted from indoor lighting such as LED (light-emitting diode). For example, applications that can be completely powered by a 100 cm² organic photovoltaic cell with 20% efficiency in typical room lighting with an LED include: calculators, wristwatches, scales, alarm clocks, wireless mouse, hand held radios, toys, remote controllers, motion detectors, smoke detectors, door lock remotes, laser pointers, flashlights, lamps, light sensors, garden lights, automatic dispensers, mobile phones and communication devices.

### Examples

### Device Optimization Procedure: General Approach

Nanoparticle devices were fabricated from two types of nanoparticles: “blend nanoparticles” contain both P3HT and PCBM within each nanoparticle, while “separate nanoparticles” contain nanoparticles of only P3HT and nanoparticles of only PCBM. In the present context we will mostly talk about the optimization procedure based on blend nanoparticle devices for simplicity, although a similar protocol can be applied to separate nanoparticles assemblies of OPVs as well. The optimum device architecture is shown in FIG. 6a. FIG. 6b is the top SEM image of blend nanoparticles spin coated on Si substrate. There is no PCBM buffer layer on top. FIG. 6c shows the cross sectional SEM image of blend nanoparticles coated on Si substrate followed by PCBM buffer layer on top. Devices, fabricated using various processing conditions show a significant improvement in the PCE ranging from 0.3% to 2.15%. Details of these six processes are given bellow in the preferred order.

Process P1: Nanoparticles active layer was spin coated on as prepared PEDOT:PSS layer. No buffer layer was present.

Process P2: Active layer was spin coated on UV-O₃ treated PEDOT:PSS layer. No buffer layer was present.

Process P3: Active layer was spin coated on as prepared PEDOT:PSS layer. A thin PCBM buffer layer was spin coated on top from 15 mg/mL in dichloromethane solution at 1000 rpm speed for 40 second.

Process P4: Active layer was spin coated on UV-O₃ treated PEDOT:PSS substrate. A thin PCBM buffer layer was spun on top from 15 mg/mL in dichloromethane solution.

Process P5: Active layer was spin coated on UV-O₃ treated PEDOT:PSS substrate. Active layer was then washed with ethanol solution before PCBM buffer layer was spun on top.

Process P6: 20% ethanol in water was added to nanoparticle dispersion before final centrifugal filtration. Active layer was then spin coated on UV-O₃ treated PEDOT:PSS substrate. A thin PCBM buffer layer was then spin coated on top.

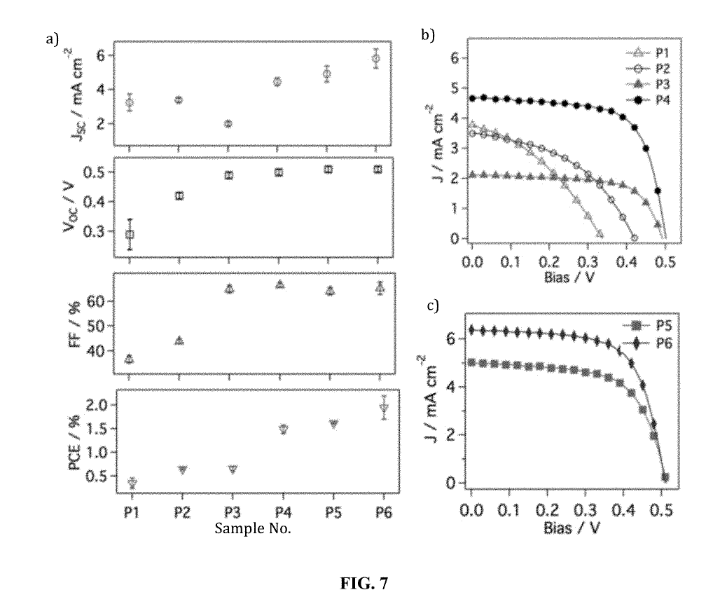

All devices were coated with 15 nm of Ca electrode at 0.5 Å s⁻¹ rate followed by 100 nm of Al coating as encapsulation to the Ca electrode at 1-3 Å s⁻¹ rate at a chamber pressure of 10⁻⁶ mbar. Devices were then heated slowly from 30° C. to 150° C. and taken off from the hot plate for electrical measurement. The device performances as a function of processing condition are shown in FIG. 7a and their corresponding current-voltage (I-V) curves have been shown in FIG. 7b and FIG. 7c. Significant improvement in terms of V_{OC} and FF was observed from process P1 to process P2. Introduction of additional PCBM as ETL maximizes V_{OC} and FF, however J_{SC} was significantly low in process P3 devices. This could be attributed to the surface roughness of the film and a thick PCBM buffer layer. Significant improvement in PCE was observed in process P4 where PEDOT:PSS substrate was treated with UV-O₃ and a thin PCBM buffer layer was spin coated on top indicating the importance of both the processing condition. With the ethanol wash (P5), higher V_{OC} (0.52 V) was observed than process P4. The optimum device performance was achieved in process P6 where 20% ethanol was added to the nanoparticle dispersion and centrifuged further to obtain required concentration of polymer ink. The enhancement in the PCE is mostly due to the enhancement in current density J_{SC}.

### Impact of Post-Heat Treatment on Device Performance

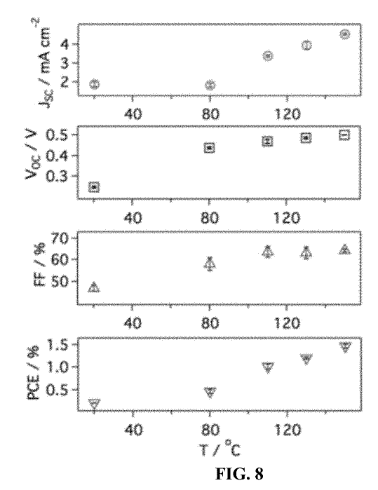

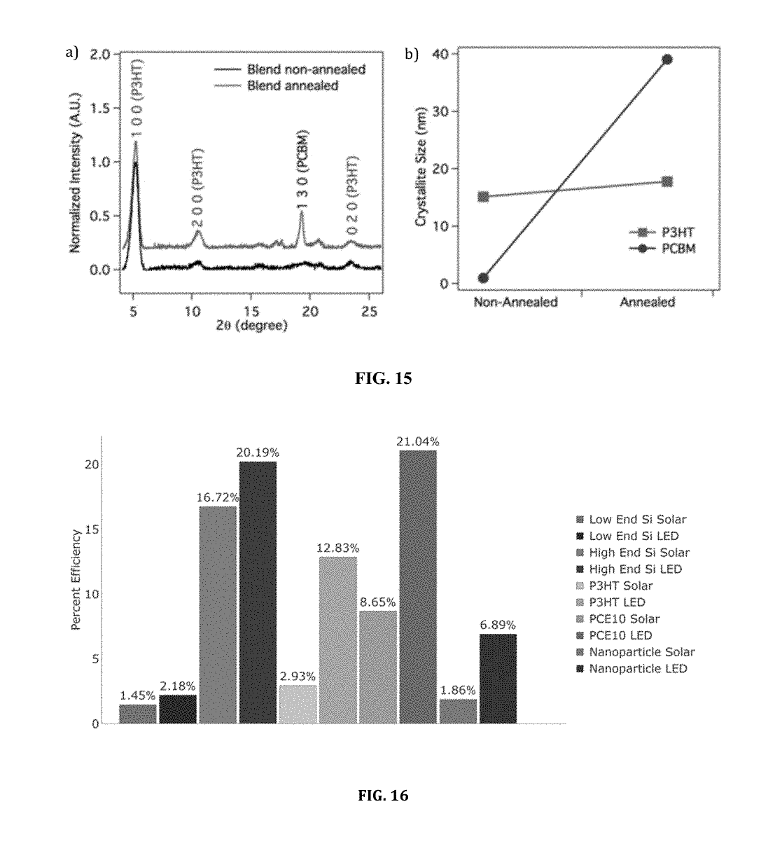

It was important to study the impact of thermal annealing. As the nanoparticles are preformed to pre-aggregated structure, it is expected that the thermal annealing would not affect the polymer crystallinity and hence the device efficiency. In fact in literature it has been shown that after thermal annealing, efficiency goes down for P3HT/PCBM blend nanoparticle solar cells. (Darwis, et al. 2014 Sol. Energy Matter. & Sol. Cells 121, 99.) We have demonstrated that controlled heat treatment (post-heating) is required for optimum device performance. In FIG. 8 the device performance as a function of temperature is shown. In all the measurements, substrates were slowly heated from 30° C. to the final temperature with a heating rate of 5-10° C. min⁻¹. We believe slow heating of the substrate improves the interfacial coupling between polymer nanoparticles and PEDOT:PSS layer as well as PCBM and the cathode layer. (Chen, et al. 2010 Nano Letters 11, 561.) Significant improvement in V_{OC} as well as FF was observed when the devices were heated up to 80° C. which was well below the crystal re-orientation temperature (Tₘ˜195° C.) for P3HT. (Verploegen, et al. 2010 Adv. Funct. Mater. 20, 3519.) J_{SC} was increased only when devices were heated above 110° C. This could be due to PCBM cold crystallization which occurs in the temperature rage of 103-119° C. for P3HT/PCBM blend of 1:1 ratio. (Verploegen, et al. 2010 Adv. Funct. Mater. 20, 3519.) P3HT crystallinity does not alter after heating up to 150° C. as estimated from x-ray diffraction (FIG. 15) although a strong crystalline peak from PCBM is observed after heating at 150° C. As P3HT and PCBM are miscible and single glass transition temperature (T_{g}) is observed at any composition, any structural changes would happen during nanoparticle synthesis at a temperature 80° C. as T_{g} for P3HT/PCBM blend (1:1) is less than 40° C. (Zhao, et al. 2009 J. Phys. Chem. B 113, 1587; Trinh Tung, et al. 2012 Advances in Natural Sciences: Nanoscience and Nanotechnology 3, 045001.) However over heating of these substrates cause decrease in efficiency.

### Impact of UV-O₃ Treatment and ETL on Device Performance

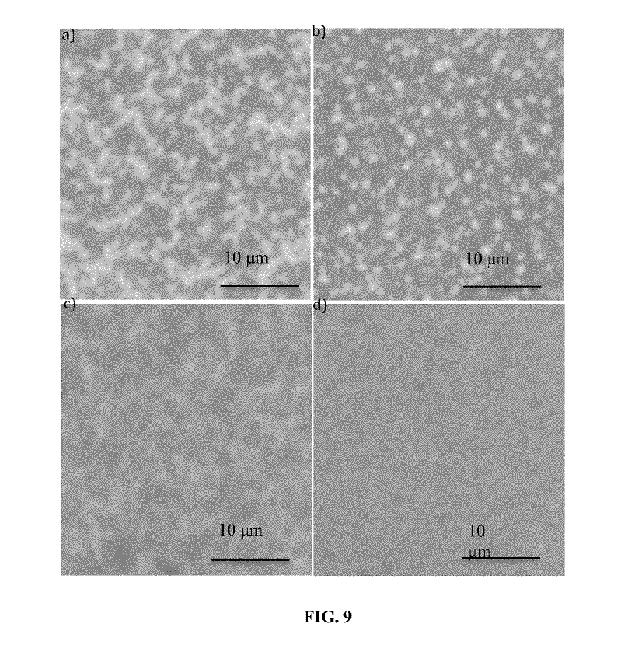

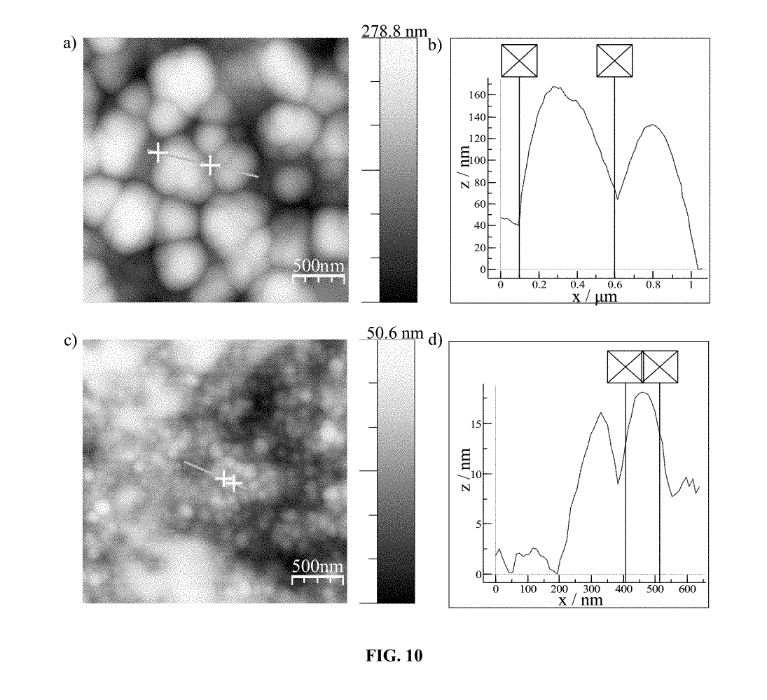

The film quality of nanoparticle assembly improves significantly from process P1 to process P2. Optical images in FIG. 9a show large aggregate of polymer nanoparticles and crack formation in the film prepared by process P1 compared to that of process P2 (FIG. 9b). FIGS. 9c & 9d are the optical images of the devices P3 and P4 respectively demonstrating PCBM buffer layer reduces the surface roughness. We believe that the large aggregates of the nanoparticles and crack formation observed in the film of process P1 was due to de-wetting properties of polymer nanoparticles ink. The contact angle of as prepared PEDOT:PSS coated substrate was estimated to be advancing angle θ_{A}≈15° and receding angle θ_{R}≈8° where as after UV-O₃ treatment advancing angle θ_{A} was less than 2° and water droplet started spreading very rapidly. In FIG. 10a and FIG. 10b AFM image of P3HT/PCBM blend nanoparticles film prepared by process P1 indicates the presence of large aggregates on the order of 500 nm to 1000 nm range. The surface roughness was ˜70 nm. Large leakage current due to low shunt resistance (Rₛₕ) gives rise to low FF and V_{OC}. The typical Rₛₕ value measured was 294 Ω-cm². In case of process P2, nanoparticles were more uniformly spread and less or no such large aggregates or cracks were observed. Series resistance (Rₛ) of these devices was still very high (on the order of 40-50 Ω-cm²). A thin layer of PCBM buffer layer further reduces the surface roughness as demonstrated in FIG. 10c and FIG. 10d. The surface roughness was on the order of 10-20 nm. The shunt resistance Rₛₕ increased up to ˜474 Ω-cm² without the PCBM top layer (P2) and it was ˜1.5 kΩ-cm² with the buffer layer (P4). Additional processing such as removing excess surfactant from the film surface by ethanol wash as described in process P5 improved the charge extraction at the cathode interface and slight increase in V_{OC} was observed. However significant improvement in the current density has been achieved from the process P6 when the polymer nanoparticles were re-suspended in 20% ethanol and 80% of water (by volume) mixture after 4^{th} times centrifugal filtration. We believe the improvement in the current density is due to better packing of the nanoparticles when spin coated from 20% of ethanol solution. However detail study is needed to understand the mechanism of polymer nanoparticles self-assembly from aqueous dispersion as it governs by the interplay of nanoscale forces such as attractive hydrophobic force, mainly due to van-der Waals interaction, and repulsive electrostatic force due to charge on the nanoparticles. (Choueiri, et al. 2013 J. Am. Chem. Soc. 135, 10262.)

### Light Intensity Dependent Study, Structure-Properties Correlation

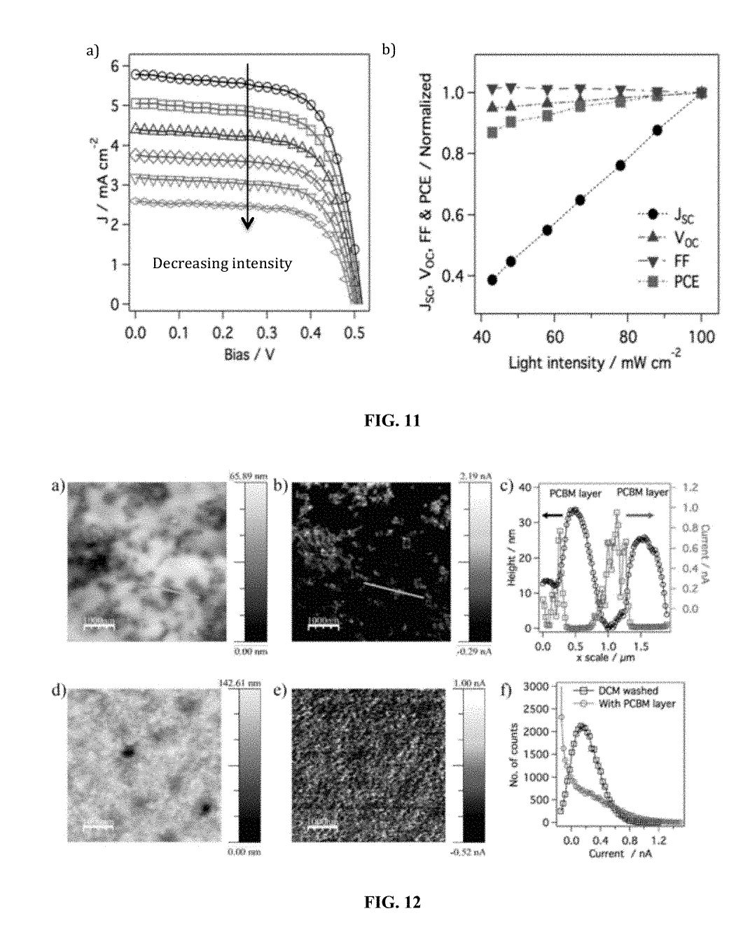

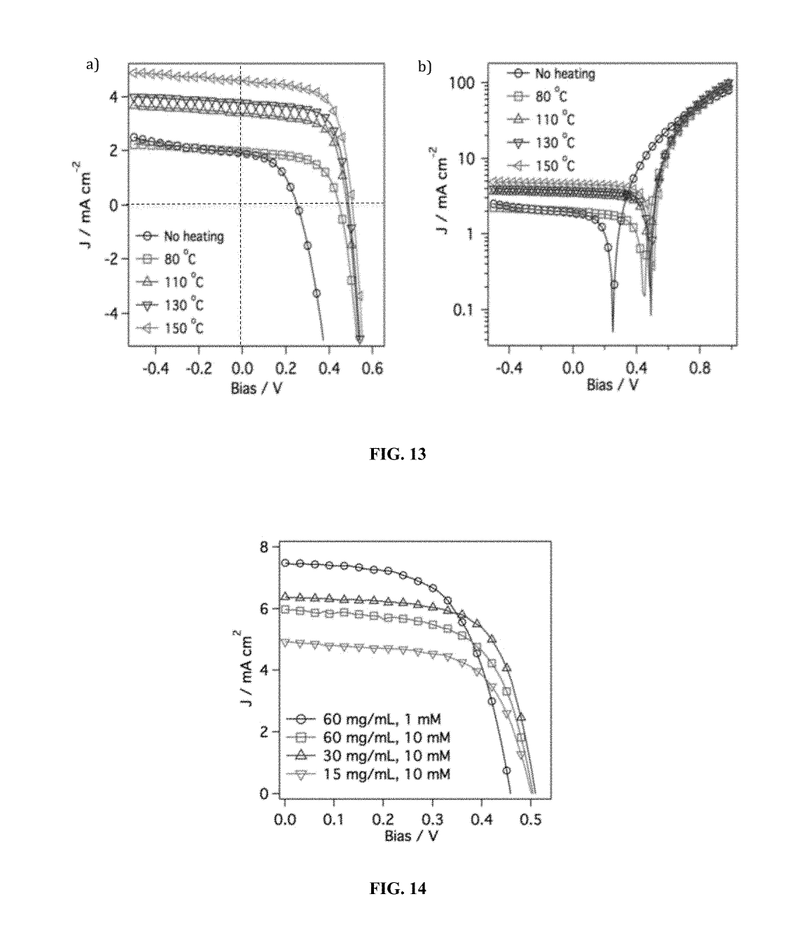

To understand the device performance parameters we carried out intensity dependent I-V measurement on one of the good devices (PCE˜2.0%). The I-V curve at different intensity of light is shown in FIG. 11a. High FF over 67% even at 100 mW cm⁻² intensity of light indicates a balance transport of electron and holes to the respective electrodes and lack of bimolecular recombination losses. J_{SC} was linearly dependent on the light intensity as shown in the FIG. 11b. However, slight drop in efficiency as light intensity was decreased was mainly due to the drop in V_{OC}. Conducting AFM (c-AFM) measurement of efficient solar cells has been carried out to understand the charge transport. FIGS. 11a & 11b show AFM topographic and current contrast image of P3HT/PCBM blend nanoparticles respectively. It is observed that PCBM buffer layer prevents the hole transport towards the top (cathode) electrode (FIG. 12c). Hence a significant improvement in FF and V_{OC} is observed. However after washing the film with dichloromethane (DCM), PCBM buffer layer was removed (FIG. 12d) and c-AFM indicates uniform conduction pathways for the holes (FIG. 12e). A quantitative analysis of conduction pathways with and without PCBM buffer layer shown in FIG. 12f is in good agreement with low leakage current and high FF observed in these devices.

### Impact of External Parameters; Polymer Ink, RH Factor and IR Heating

The film preparation was optimized based on two other external parameters; relative humidity (RH) and substrate temperature. The film drying process should not be too slow such that PEDOT:PSS substrates get dissolved in polymer ink. It is therefore important to either pre-heat the substrate or heating the substrate while spin coating the polymer ink. Substrate can have radiative heating using infrared (IR) lamp. The film thickness can be controlled by the spin coating speed and amount of substrate pre-heating or heating during spin coating. It is noticed that ˜30% RH is optimum for the device fabrication. At low RH, film becomes porous and surface roughness increases. It is also noticed that the film on ITO substrate is more rough than the film on glass side even though 40 nm of PEDOT:PSS was spin coated on both sides. This phenomenon could be due to the difference of heat absorbed by glass and ITO substrate (see SI). It is known that ITO reflects near infrared and always at a lower temperature than the glass slide. The nanoparticles size and the amount of surfactant left on the particles have also an impact on the film formation and surface roughness as the viscosity of the polymer ink depends on those factors. It has been observed that reducing the particle size by decreasing the polymer concentration to 15 mg/mL in chloroform gives rise to smooth film with high reproducibility. However PCE of these films are lower (˜1.5%) than the devices fabricated from 30 mg/mL of polymer in chloroform (˜2.0%). It was also important to filter the as prepared dispersion more times (7 times centrifuged for 15 mg/mL initial concentration of polymer to 5 times centrifuged for 30 mg/mL initial concentration of polymer in chloroform). Further increase in the polymer concentration does not improve the PCE, however reduces the ink viscosity and hence film thickness.

Comparison with Commercial Silicon-Based Solar Cells

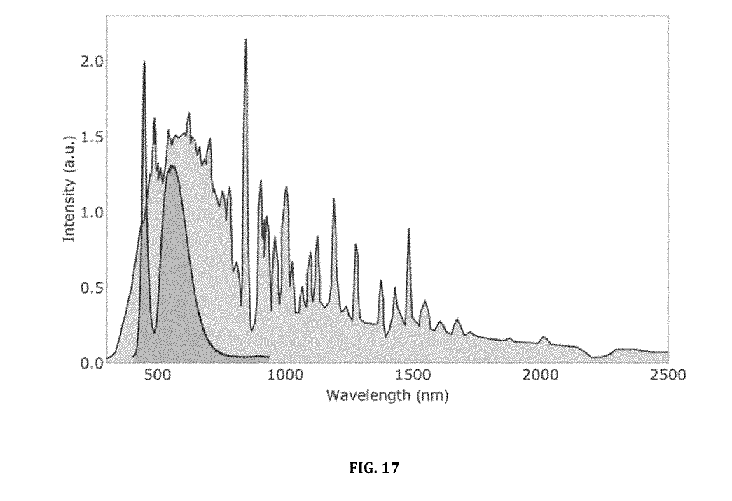

Exemplary OPV cells according to the present invention were comparatively tested against various commercial silicon-based solar cells or devices. As shown in FIG. 16, the results showed that the exemplary OPVs disclosed herein outperformed certain existing, commercial silicon-based solar cells in outdoor and/or indoor lighting conditions. In FIG. 16, the “Low End Si” refers to a commercial silicon photovoltaic attached to a toy. The “High End Si” refers to commercial silicon photovoltaic attached to an LED lamp. The “P3HT” refers to a P3HT and PCBM bulkheterojunction organic photovoltaic device. The “PCE10” refers to a PCE10 and PCBM bulkheterojunction organic photovoltaic device. The “Nanoparticle” refers to a P3HT and PCBM nanoparticle organic photovoltaic device prepared as described above. The emission spectra of solar simulator lamp (outdoor) and cool white LED lamp (indoor) are shown in FIG. 17. These results demonstrates that in combination with their low manufacturing cost, lightweight and flexible devices makes the OPV devices of the present invention very attractive for a wide-range of applications, such as cell phone chargers, small LED lights on products or stripes on floors, toys, alarm clocks, calculators, wireless sensors, etc.

### Experimental

### Nanoparticle Preparation: Synthesis of P3HT/PCBM Blended Nanoparticles

P3HT and PCBM were combined and dissolved in chloroform to form a 30 mg/mL solution. This solution was heated and stirred for 30 min at 35° C. to ensure solubility. 10 mM SDS solutions were prepared using nanopure water, then warmed and sonicated using VWR Aquasonic bath sonicator to ensure complete solubility. 3 mL SDS solution was added to a 15 mL centrifuge tube. 0.5 mL of the 30 mg/mL P3HT and PCBM blend solution was added to the SDS solution. The resulting solution was immediately ultrasonicated using MISONIX probe ultrasonicator for 2 minutes at 20% max amplitude with a ⅛″ probe tip. During ultrasonication, the probe tip was submerged just below the tube's tapering into the solution and made sure that the probe was not touching the sides of the tube throughout the ultrasonication. The centrifuge tube was placed in an ice water bath during sonication. After ultrasonication, the emulsion was poured into a glass vial and heated at 70° C. for 40 min with constant stirring. This is repeated for a second sample.

To remove excess surfactant floating in the nanoparticle solution, both solutions were added to 6 mL centrifugal concentrator tube (10 kDa MWCO) and centrifuged at 4185 rcf for 25 min. The retentate volume was then raised to approximately 5 mL with nanopure water, resuspending the nanoparticles, and the samples were gently mixed and centrifuged again. This was repeated another two times, four times total. For the fifth and final centrifugation cycle, the retenate was raised to 5 mL with a 20 vol % ethanol in water solution. This solution was centrifuged for 38 min at 4185. Upon centrifugation the retentate volume was raised to 0.5 mL with 20 vol % ethanol in water solution. This concentrated solution is then used in the spin coating.

For the separate nanoparticle solutions, two separate nanoparticle solutions are prepared: 30 mg/mL P3HT in chloroform and 30 mg/mL PCBM in chloroform. Both solutions are then combined and mixed within a 6 mL centrifugal concentrator tube (10 kDa MWCO). Upon which the same centrifugal filtration process is performed.

### Device Fabrication

ITO substrates were cleaned by ultrasonication in soap solution, rinsed several times with distilled water, followed by ultrasonication in acetone and isopropyl alcohol. Substrates were then kept in hot-air oven at 90° C. for about 3 hours. Cleaned ITO substrate were then treated with UV/ozone cleaner for about 15 minutes before PEDOT:PSS was spin-coated in ambient at 2500 rpm for 40 sec. PEDOT:PSS coated substrate were annealed at 150° C. for 30 minutes and cooled it down to room temperature. Substrates were then kept in UV/ozone cleaner for 3 minutes. Nanoparticle dispersion was then spin coated onto PEDOT:PSS coated ITO substrates at 1000 rpm for 50 second in presence of infra-red lamp on top. Nanoparticle-coated substrates were then kept in a vacuum chamber for 12 hours. PCBM buffer layer was spin coated onto the active layer at 1000 rpm from 15 mg/ml concentration in dichloromethane solution inside glove box and then transferred to electrode deposition chamber. At chamber pressure of 1×10⁻⁶ mbar, 15 nm of Ca was evaporated using a shadow mask of 6 mm² area at 0.5 Å/sec deposition rate followed by 100 nm of Al electrode deposited at 1-3 Å/sec deposition rate. Devices were then annealed slowly from 30° C. to 150° C. inside glove box and tested under AM 1.5G solar simulator at 100 mW/cm² light intensity.

### TOF Measurement

TOF mobility measurement of P3HT only, P3HT and PCBM separate and blend nanoparticle samples. Films were prepared from concentrated solution of nanoparticle dispersion spin coated slowly (600 rpm) in presence of infrared (IR) lamp. Film thickness was typically of 1 to 2 micrometer. A thin layer (30 nm) of Al electrode was used to illuminate through the electrode. 355 nm laser pulse (10 ns) was used for photo carriers' generation.

### Conducting AFM Measurement

c-AFM measurements were performed using the ORCA cantilever holder with a trans-impedance amplifier with the Asylum Research MFP-3D microscope. Topography and current measurements were performed simultaneously in contact mode with either a Cr/Pt coated Si probe (Budget Sensors ContE-G, Force Constant=0.2 N/m) or an Ir/Pt coated Si probe (AppNano ANSCM-PT, Force Constant=1-5 N/m). In general, a 10 μm×10 μm (512×512 pxl) scan was conducted at a scan rate of 0.5 Hz, and an applied sample voltage of +2.0V. The sample was held on the ORCA sample mount, and connected using the attached clip to a small area of ITO where the active layer has been scraped away.

In this specification and the appended claims, the singular forms “a,” “an,” and “the” include plural reference, unless the context clearly dictates otherwise. Unless defined otherwise, all technical and scientific terms used herein have the same meaning as commonly understood by one of ordinary skill in the art. Methods recited herein may be carried out in any order that is logically possible, in addition to a particular order disclosed.

### INCORPORATION BY REFERENCE

References and citations to other documents, such as patents, patent applications, patent publications, journals, books, papers, web contents, have been made in this disclosure. All such documents are hereby incorporated herein by reference in their entirety for all purposes. Any material, or portion thereof, that is said to be incorporated by reference herein, but which conflicts with existing definitions, statements, or other disclosure material explicitly set forth herein is only incorporated to the extent that no conflict arises between that incorporated material and the present disclosure material. In the event of a conflict, the conflict is to be resolved in favor of the present disclosure as the preferred disclosure.

### EQUIVALENTS

The representative examples are intended to help illustrate the invention, and are not intended to, nor should they be construed to, limit the scope of the invention. Indeed, various modifications of the invention and many further embodiments thereof, in addition to those shown and described herein, will become apparent to those skilled in the art from the full contents of this document, including the examples and the references to the scientific and patent literature included herein. The examples contain important additional information, exemplification and guidance that can be adapted to the practice of this invention in its various embodiments and equivalents thereof.

1. A photovoltaic device comprising:
a transparent electrode;
an electron-blocking layer;
an active layer comprising a plurality of nanoparticles comprising a conjugated polymer;
a buffer layer; and
a counter electrode,
wherein
the electron-blocking layer is pre-treated with UV and ozone; and
the plurality of nanoparticles comprise electron conductors and hole conductors.

2. The photovoltaic device of claim 1, wherein the active layer is formed under IR radiation from an aqueous dispersion of a plurality of nanoparticles comprising a conjugated polymer.

3. The photovoltaic device of claim 1, wherein the plurality of nanoparticles have a size range from 30 nm to 150 nm

4. The photovoltaic device of claim 1, wherein the plurality of nanoparticles comprise
nanoparticles each of which comprises both electron conductors and hole conductors.

5. The photovoltaic device of claim 4, wherein each of the plurality of nanoparticles comprises both poly-3-hexylthiophene (P3HT) and phenyl-C₆₁-butyric acid methyl ester or its C₇₀ analog (collectively termed as PCBM).

6. The photovoltaic device of claim 4, wherein each of the plurality of nanoparticles comprises copolymers derived from diketopyrrolopyrrole and thiophene.

7. The photovoltaic device of claim 4, wherein each of the plurality of nanoparticles comprises copolymers derived from DPP-BT, poly((2-ethylhexyl)oxy benzodithiophene-alt-3-fluoro-2-[(2-ethylhexyl)carbonyl] thieno[3,4-b]thiophene) (PTB7), Poly[2,6-(4,4-bis-(2-ethylhexyl)-4H-cyclopenta [2,1-b; 3,4-b′]dithiophene)-alt-4,7(2,1,3-benzothiadiazole)] (PCPDTBT), 1′,1″,4′,4″-tetrahydro-di[1,4]methano-naphthaleno[5,6]fullerene-C₆₀.

8. The photovoltaic device of claim 1, wherein the plurality of nanoparticles comprise
nanoparticles each of which comprises electron conductors and not hole conductors; and
nanoparticles each of which comprises hole conductors and not electron conductors.

9. The photovoltaic device of claim 8, wherein the plurality of nanoparticles comprise
nanoparticles each of which comprises poly-3-hexylthiophene (P3HT) and not phenyl-C₆₁-butyric acid methyl ester (PCBM); and
nanoparticles each of which comprises phenyl-C₆₁-butyric acid methyl ester (PCBM) and not poly-3-hexylthiophene (P3HT).

10. The photovoltaic device of claim 1, wherein the transparent electrode is made from a material selected from transparent conducting oxides (TCO).

11. The photovoltaic device of claim 1, wherein the transparent electrode is made from indium doped tin oxide (ITO).

12. The photovoltaic device of claim 1, wherein the counter electrode is made from a material selected from low work-function materials.

13. The photovoltaic device of claim 1, wherein the counter electrode is made from one or both of Ca and Al.

14. The photovoltaic device of claim 1, wherein the electron-blocking layer comprises UV and ozone-treated poly(3,4-ethylenedioxythiophene) poly(styrenesulfonate) (PEDOT:PSS).

15. The photovoltaic device of claim 1, wherein the electron-blocking layer comprises UV and ozone-treated MoO₃.

16. The photovoltaic device of claim 1, having a power conversion efficiency (PCE) of about 1.56% to about 2.15%.

17-19. (canceled)

20. An article of manufacture comprising the photovoltaic device of claim 1.

21. (canceled)

22. A method for making a photovoltaic device, comprising:
providing a transparent electrode;
forming a dried electron-blocking layer on the transparent electrode;
treating the dried electron-blocking layer with UV and ozone;
applying under IR radiation, on the treated electron-blocking layer, a layer of an aqueous dispersion of a plurality of nanoparticles comprising a conjugated polymer;
drying the layer of aqueous dispersion of a plurality of nanoparticles to form a dried active layer;
forming a buffer layer on the dried active layer; and
forming a counter electrode on the buffer layer.

23-32. (canceled)

33. A photovoltaic device produced by the method of claim 22.

34-36. (canceled)

37. A method for making a photovoltaic active layer, comprising:
forming an aqueous dispersion of a plurality of nanoparticles of controlled size and morphology under IR radiation, wherein the nanoparticles comprise a conjugated polymer; and
drying the layer of aqueous dispersion of a plurality of nanoparticles to obtain a dried photovoltaic active layer.

38-42. (canceled)
